(19) United States
(12) Patent Application Publication
(10) Pub. No.: US 2003/0134495 A1
(43) Pub. Date: Jul. 17, 2003

(54) Integration scheme for advanced BEOL metallization including low-k cap layer and method thereof

(75) Inventors: Stephen Gates, Ossining, NY (US); Birendra N. Agarwala, Hopewell Junction, NY (US); John A. Fitzsimmons, Poughkepsie, NY (US); Jia Lee, Ossining, NY (US); Naftali E. Lustig, Croton on Hudson, NY (US); Yun Yu Wang, Poughquag, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY

(21) Appl. No.: 10/047,968

(22) Filed: Jan. 15, 2002

(51) Int. Cl. H01L 21/44

(52) U.S. Cl. 438/600; 257/758

(57) ABSTRACT

An advanced back-end-of-line (BEOL) metallization structure is disclosed. The structure includes a diffusion barrier or cap layer having a low dielectric constant (low-k). The cap layer is formed of amorphous nitrogenated hydrogenated silicon cabride, and has a dielectric constant (k) of less than about 5. A method for forming the BEOL metallization structure is also disclosed, where the cap layer is deposited using a plasma-enhanced chemical vapor deposition (PE CVD) process. The invention is particularly useful in interconnect structure comprising low-k dielectric material for the inter-layer dielectric (ILD) and copper for the conductors.

### FIELD OF THE INVENTION

This invention relates generally to the manufacture of high speed semiconductor microprocessors, application specific integrated circuits (ASICs), and other high speed integrated circuit devices. More particularly, this invention relates to an advanced back-end-of-line (BEOL) integration scheme for semiconductor devices using low-k dielectric materials. The invention is specifically directed to an advanced BEOL metallization structure which includes a cap layer having a low dielectric constant (low-k), and a method for forming the BEOL metallization structure.

### BACKGROUND OF THE INVENTION

Metal interconnections in very large scale integrated (VLSI) or ultra-large scale integrated (ULSI) circuits typically consist of interconnect structures containing patterned layers of metal wiring. Typical integrated circuit (IC) devices contain from three to fifteen layers of metal wiring. As feature size decreases and device areal density increases, the number of interconnect layers is expected to increase.

The materials and layout of these interconnect structures are preferably chosen to minimize signal propagation delays, hence maximizing the overall circuit speed. An indication of signal propagation delay within the interconnect structure is the RC time constant for each metal wiring layer, where R is the resistance of the wiring and C is the effective capacitance between a selected signal line (i.e., conductor) and the surrounding conductors in the multilevel interconnect structure. The RC time constant may be reduced by lowering the resistance of the wiring material. Copper is therefore a preferred material for IC interconnects because of its relatively low resistance. The RC time constant may also be reduced by using dielectric materials with a lower dielectric constant, k.

State-of-the-art dual damascene interconnect structures comprising low-k dielectric material and copper interconnects are described in “A High Performance 0.13 μm Copper BEOL Technology with Low-k Dielectric,” by R. D. Goldblatt et al., Proceedings of the IEEE 2000 International Interconnect Technology Conference, pp. 261-263. A typical interconnect structure using low-k dielectric material and copper interconnects is shown in FIG. 1. The interconnect structure comprises a lower substrate 10 which may contain logic circuit elements such as transistors. A dielectric layer 12, commonly known as an inter-layer dielectric (WLD), overlies the substrate 10. In advanced interconnect structures, ILD layer 12 is preferably a low-k polymeric thermoset material such as SiLK™ (an aromatic hydrocarbon thermosetting polymer available from The Dow Chemical Company). An adhesion promoter layer 11 may be disposed between the substrate 10 and ILD layer 12. A layer of silicon nitride 13 may be disposed on ILD layer 12. Silicon nitride layer 13 is commonly known as a hardmask layer or polish stop layer. At least one conductor 15 is embedded in ILD layer 12. Conductor 15 is typically copper in advanced interconnect structures, but may alternatively be aluminum or other conductive material. A diffusion barrier liner 14 may be disposed between ILD layer 12 and conductor 15. Diffusion barrier liner 14 is typically comprised of tantalum, titanium, tungsten or nitrides of these metals. The top surface of conductor 15 is made coplanar with the top surface of silicon nitride layer 13, usually by a chemical-mechanical polish (CMP) step. A cap layer 16, also typically of silicon nitride, is disposed on conductor 15 and silicon nitride layer 13. Silicon nitride cap layer 16 acts as a diffusion barrier to prevent diffusion of copper from conductor 15 into the surrounding dielectric material.

A first interconnect level is defined by adhesion promoter layer 11, ILD layer 12, silicon nitride layer 13, diffusion barrier liner 14, conductor 15, and cap layer 16 in the interconnect structure shown in FIG. 1. A second interconnect level, shown above the first interconnect level in FIG. 1, includes adhesion promoter layer 17, ILD layer 18, silicon nitride layer 19, diffusion barrier liner 20, conductor 21, and cap layer 22. The first and second levels may be formed by conventional damascene processes. For example, formation of the second interconnect level begins with deposition of adhesion promoter layer 17. Next, the ILD material 18 is deposited onto adhesion promoter layer 17. If the ILD material is a low-k polymeric thermoset material such as SiLK™, the ILD material is typically spin-applied, given a post apply hot bake to remove solvent, and cured at elevated temperature. Next, silicon nitride layer 19 is deposited on the ILD. Silicon nitride layer 19, ILD layer 18, adhesion promoter layer 17 and cap layer 16 are then patterned, using a conventional photolithography and etching process, to form at least one trench and via. The trenches and vias are typically lined with diffusion barrier liner 20. The trenches and vias are then filled with a metal such as copper to form conductor 21 in a conventional dual damascene process. Excess metal is removed by a CMP process. Finally, silicon nitride cap layer 22 is deposited on copper conductor 21 and silicon nitride layer 19.

However, silicon nitride has a relatively high dielectric constant of about 6 to 7. Fringing electric fields between the copper conductors are known to be present in regions of the copper where a higher-k cap/diffusion barrier film such as silicon nitride is present. When a material having a low dielectric constant of about 2 to 3 is used for the ILD, the effective capacitance of the metal conductors is increased by using a higher-k silicon nitride cap/diffusion barrier layer, resulting in decreased overall interconnect speed. The effective capacitance is also increased by using a higher-k silicon nitride polish-stop layer.

In addition, interconnect structures using a silicon nitride hardmask layer may suffer from decreased reliability and higher failure rates. Interconnect structures are typically subjected to testing under accelerated stress conditions in order to identify weak points within the structure. Temperatures of about 200 to 300° C. are employed to accelerate the rate of processes leading to failure. One class of tests uses high humidity conditions to accelerate oxidation by water vapor, and another class uses higher current density to accelerate the effects of current flow on the metal interconnect structures. Interconnect structures using low-k dielectric material and copper conductors along with a silicon nitride hardmask layer suffer from unacceptably high failure rates when subjected to these accelerated stress conditions.

An alternative material for cap layers 16 and 22 is an amorphous hydrogenated silicon carbide material (SiₓC_{y}H_{z}), one example being the material known as Blok™ (an amorphous film composed of silicon, carbon and hydrogen, which is available from Applied Materials, Inc.). SiₓC_{y}H_{z} has a dielectric constant of less than 5, which is much lower than that of silicon nitride. Thus, in an interconnect structure using SiₓC_{y}H_{z} for the cap layer, the effective capacitance of the metal conductors is decreased, and the overall interconnect speed is increased.

However, it has been discovered that electromigration rates are relatively high in interconnect structures comprising copper conductors and low-k ILD with a cap layer of SiₓC_{y}H_{z}. These high electromigration rates often result in rapid failure of the IC chip.

Thus, there is a need in the art for an interconnect structure utilizing copper or aluminum conductors, a low-k ILD having a dielectric constant of about 2 to 3, and a cap layer which has a dielectric constant of less than about 5, and which also provides effective oxygen barrier properties.

### SUMMARY OF THE INVENTION

The problems described above are addressed through use of the present invention, which is directed to an interconnect structure formed on a substrate. In a preferred embodiment, the structure comprises a dielectric layer overlying the substrate; a hardmask layer on the dielectric layer, said hardmask layer having a top surface; at least one conductor embedded in said dielectric layer and having a surface coplanar with the top surface of said hardmask layer; and a cap layer on said at least one conductor and on said hardmask layer, said cap layer having a bottom surface in strong adhesive contact with said conductor, wherein said cap layer is formed of a material including silicon, carbon, nitrogen and hydrogen.

In an alternative embodiment, the structure comprises a dielectric layer overlying the substrate, said dielectric layer having a top surface; a conductor embedded in said dielectric layer and having a surface coplanar with the top surface of said dielectric layer; and a cap layer on said conductor, wherein said cap layer is formed of a material including silicon, carbon, nitrogen and hydrogen.

The present invention is also directed to a method of forming an interconnect structure on a substrate. In one embodiment, the method comprises the steps of: depositing a dielectric material on the substrate, thereby forming a dielectric layer, said dielectric layer having a top surface; forming an opening in said dielectric layer; filling said opening with a conductive material, thereby forming a conductor, said conductor having a surface coplanar with the top surface of said dielectric layer; and depositing a cap material on said conductor, said cap material including silicon, carbon, nitrogen and hydrogen, thereby forming a cap layer.

In another embodiment, the method comprises the steps of: depositing a dielectric material on the substrate, thereby forming a dielectric layer; depositing a hardmask material on said dielectric layer, thereby forming a hardmask layer, said hardmask layer having a top surface; forming an opening in said hardmask layer and said dielectric layer; filling said opening with a conductive material, thereby forming a conductor, said conductor having a surface coplanar with the top surface of said hardmask layer; and depositing a cap material on said conductor, said cap material including silicon, carbon, nitrogen and hydrogen, thereby forming a cap layer.

The cap layer of the invention has a dielectric constant of less than about 5. When used in combination with a low-k dielectric material having a dielectric constant of less than about 3, and with an optional hardmask layer formed of a material having a dielectric constant less than about 5, the effective capacitance of the interconnect structure is reduced as compared to prior art structures. This lower effective capacitance results in an improvement in overall IC chip speed.

In addition, the cap layer of this invention provides improved oxygen barrier properties. By providing an effective barrier to oxygen, the cap layer protects the conductor from oxygen diffusion and the formation of oxides on the conductor surface. Elimination of such oxides is believed to inhibit copper transport, thereby lowering electromigration rates and resulting in reduced IC chip failures.

### BRIEF DESCRIPTION OF THE DRAWINGS

The features of the invention believed to be novel and the elements characteristic of the invention are set forth with particularity in the appended claims. The drawings are for illustration purposes only and are not drawn to scale. Furthermore, like numbers represent like features in the drawings. The invention itself, however, both as to organization and method of operation, may best be understood by reference to the detailed description which follows, taken in conjunction with the accompanying drawings, in which:

FIG. 1 is a schematic cross-sectional view of a partially-fabricated integrated circuit device illustrating a prior art interconnect structure;

FIG. 2 is a schematic cross-sectional view of a partially-fabricated integrated circuit device illustrating an interconnect structure in accordance with a preferred embodiment of the invention;

FIG. 3 is a schematic cross-sectional view of a partially-fabricated integrated circuit device illustrating an interconnect structure in accordance with an alternative embodiment of the invention; and

FIGS. 4(a)-4(i) illustrate a method for forming the interconnect structure of FIG. 2.

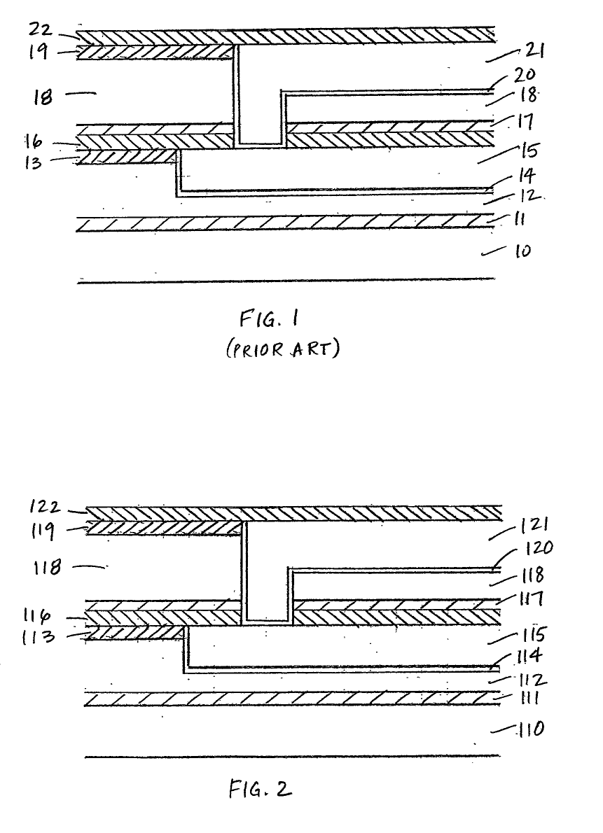

### DETAILED DESCRIPTION OF THE INVENTION

The invention will now be described by reference to the accompanying figures. In the figures, various aspects of the structures have been shown and schematically represented in a simplified manner to more clearly describe and illustrate the invention. For example, the figures are not intended to be to scale. In addition, the vertical cross-sections of the various aspects of the structures are illustrated as being rectangular in shape. Those skilled in the art will appreciate, however, that with practical structures these aspects will most likely incorporate more tapered features. Moreover, the invention is not limited to constructions of any particular shape.

Although certain aspects of the invention will be described with respect to a structure comprising copper, the invention is not so limited. Although copper is the preferred conductive material, the structure of the present invention may comprise any suitable conductive material, such as aluminum.

Referring to FIG. 2, a preferred embodiment of the interconnect structure of this invention comprises a lower substrate 110 which may contain logic circuit elements such as transistors. A dielectric layer 112, commonly known as an inter-layer dielectric (ILD), overlies the substrate 110. An adhesion promoter layer 111 may be disposed between substrate 110 and ILD layer 112. A hardmask layer 113 is preferably disposed on ILD layer 112. At least one conductor 115 is embedded in ILD layer 112 and hardmask layer 113. A diffusion barrier liner 114 may be disposed between ILD layer 112 and conductor 115. The top surface of conductor 115 is made coplanar with the top surface of hardmask layer 113, usually by a chemical-mechanical polish (CMP) step. A cap layer 116 is disposed on conductor 115 and hardmask layer 113.

A first interconnect level is defined by adhesion promoter layer 111, ILD layer 112, hardmask layer 113, diffusion barrier liner 114, conductor 115, and cap layer 116 in the interconnect structure shown in FIG. 2. A second interconnect level, shown above the first interconnect level in FIG. 2, includes adhesion promoter layer 117, ILD layers 118, hardmask layer 119, diffusion barrier liner 120, conductor 121, and cap layer 122.

ILD layers 112 and 118 may be formed of any suitable dielectric material, although low-k dielectric materials are preferred. Suitable dielectric materials include carbon-doped silicon dioxide (also known as silicon oxycarbide or SiCOH dielectrics); fluorine-doped silicon oxide (also known as fluorosilicate glass, or FSG); spin-on glasses; silsesquioxanes, including hydrogen silsesquioxane (HSQ), methyl silsesquioxane (MSQ) and mixtures or copolymers of HSQ and MSQ; and any silicon-containing low-k dielectric. Examples of spin-on low-k films with SiCOH-type composition using silsesquioxane chemistry include HOSP™ (available from Honeywell), JSR 5109 and 5108 (available from Japan Synthetic Rubber), Zirkon™ (available from Shipley Microelectronics), and porous low k (ELk) materials (available from Applied Materials). For this embodiment, preferred dielectric materials are organic polymeric thermoset materials, consisting essentially of carbon, oxygen and hydrogen. Preferred dielectric materials include the low-k polyarylene ether polymeric material known as SiLK™ (available from The Dow Chemical Company), and the low-k polymeric material known as FLARE™ (available from Honeywell). ILD layers 112 and 118 may each be about 100 nm to about 1000 nm thick, but these layers are each preferably about 600 nm thick. The dielectric constant for ILD layers 112 and 118 is preferably about 1.8 to about 3.5, and most preferably about 2.5 to about 2.9.

Alternatively, ILD layers 112 and 118 may be formed of an organic polymeric thermoset material containing pores. If ILD layers 112 and 118 are formed of such porous dielectric material, the dielectric constant of these layers is preferably less than about 2.6, and is most preferably about 1.5 to 2.5. It is particularly preferred to use an organic polymeric thermoset material having a dielectric constant of about 1.8 to 2.2.

Adhesion promoter layers 111 and 117 are preferably about 9 nm thick, and are composed of silicon and oxygen, with a very small carbon content. The adhesion promoter layer is preferably comprises a silane coupling agent, and is preferably prepared from a solution of an alkoxysilane molecule in a suitable solvent, which is then spin-coated onto the substrate. A preferred alkoxysilane molecule is vinyltriacetoxysilane. Other related molecules may also be used, including but not limited to vinyltrimethoxysilane, vinyltriethoxysilane, allyltrimethoxysilane, vinyldiphenylethoxysilane, norborenyltriethoxysilane, trivinyltriethoxysilane and other related silanes containing vinyl or allyl functions. When the preferred adhesion promoter molecule, vinyltriacetoxysilane, is used and the substrate is heated to about 185° C. for about 90 seconds to remove the solvent, a preferred adhesion promoter layer is formed which contains Si—O bonds as detected by infrared spectroscopy (IR) and x-ray photoelectron spectroscopy (XPS). This adhesion promoter layer does not contain acetoxy groups as determined by IR, while the vinyl groups (C═C double bonds) are readily detected by IR. Both the Si—O bonds and the vinyl groups are thermally stable up to 440° C., as determined by IR. Adhesion promoter layers 111 and 117 are preferably about 9 nm thick, although thinner layers of about 0.5 to 9 nm thick may be used within this invention. When an organic polymeric thermoset dielectric is coated onto this adhesion promoter layer, strong adhesion of the dielectric to the substrate is observed. Without this adhesion promoter layer, the adhesion is very weak.

This embodiment includes hardmask layers 113 and 119, which are preferably formed of amorphous hydrogenated silicon carbide comprising silicon, carbon and hydrogen. Specifically, these hardmask layers are preferably composed of about 20 to 32 atomic % silicon, about 20 to 40 atomic % carbon, and about 30 to 50 atomic % hydrogen. In other words, hardmask layers 113 and 119 preferably have the composition SiₓC_{y}H_{z}, where x is about 0.2 to about 0.32, y is about 0.2 to about 0.4, and z is about 0.3 to about 0.5. A minor amount of oxygen (about 1 to 10 atomic %) may also be present in these hardmask layers. A particularly preferred composition for hardmask layers 113 and 119 is about 24 to 29 atomic % silicon, about 33 to 39 atomic % carbon, and about 34 to 40 atomic % hydrogen. This particularly preferred composition may be expressed as SiₓC_{y}H_{z}, where x is about 0.24 to 0.29, y is about 0.33 to 0.39, and z is about 0.34 to 0.4. This SiₓC_{y}H_{z} hardmask layer has a dielectric constant of less than about 5, and preferably about 4.5. Hardmask layers 113 and 119 should be in strong adhesive contact with ILD layers 112 and 118, respectively. Hardmask layers 113 and 119 are preferably in the range of about 20 to about 100 nm thick, and most preferably in the range of about 25 to about 70 nm thick.

Conductors 115 and 121 maybe formed of any suitable conductive material, such as copper or aluminum. Copper is particularly preferred as the conductive material, due to its relatively low resistance. Copper conductors 115 and 121 may contain small concentrations of other elements. Diffusion barrier liners 114 and 120 may comprise one or more of the following materials: tantalum, titanium, tungsten and the nitrides of these metals.

Cap layers 116 and 122 are formed of amorphous nitrogenated hydrogenated silicon carbide comprising silicon, carbon, nitrogen and hydrogen, and have a dielectric constant (k) of less than about 5, and preferably about 4.9. Specifically, these cap layers are preferably composed of about 20 to 34 atomic % silicon, about 12 to 34 atomic % carbon, about 5 to 30 atomic % nitrogen, and about 20 to 50 atomic % hydrogen. In other words, cap layers 116 and 122 preferably have the composition SiₓC_{y}N_{w}H_{z}, where x is about 0.2 to about 0.34, y is about 0.12 to about 0.34, w is about 0.05 to about 0.3, and z is about 0.2 to about 0.5. A particularly preferred composition for cap layers 116 and 122 is about 22 to 30 atomic % silicon, about 15 to 30 atomic % carbon, about 10 to 22 atomic % nitrogen, and about 30 to 45 atomic % hydrogen. This particularly preferred composition may be expressed as SiₓC_{y}N_{w}H_{z}, where x is about 2.2 to about 3, y is about 1.5 to about 3, w is about 1 to about 2, and z is about 3 to about 4.5. Cap layers 116 and 122 should be in strong adhesive contact with conductors 115 and 121 and hardmask layers 113 and 119, respectively. Cap layers 116 and 122 are preferably in the range of about 5 to about 120 nm thick, and most preferably in the range of about 20 to about 70 nm thick.

The cap layers of this invention, such as cap layers 116 and 122, provide an improved barrier to copper atoms or ions migrating out of the copper conductors, and also provide an improved barrier to diffusion of oxygen species (such as O₂ and H₂O) moving into the conductor. The latter oxidizing species are believed to be a principal source of failure of interconnect structures under accelerated stress conditions.

At the interface between the cap layer and the conductor, such as between cap layer 116 and conductor 115, the cap layer preferably contains less than about 1 atomic % oxygen. The oxygen concentration at this interface may be measured, for example, by Auger Electron Spectroscopy (AES) or by electron energy loss spectroscopy in a Transmission Electron Microscope (TEM). The reliability of the interconnect structure under accelerated stress conditions can be significantly improved by maintaining the oxygen content at this interface at less than about 1 atomic %. This can be achieved by subjecting the surface of the conductor to an ammonia plasma pre-clean step, which is described in more detail below.

Alternatively, the cap layer may contain a higher nitrogen concentration at the interface between the cap layer and the conductor, such as between cap layer 116 and conductor 115, than is present in the remainder of the cap layer. In other words, the bottom surface of the cap layer, which is that surface in contact with the conductor, may be enriched with nitrogen as compared to the bulk of the cap layer. The preferred nitrogen concentration at this interface is in the range of about 5 to 20 atomic %, more preferably in the range of about 10 to 15 atomic %. Nitrogen enrichment at this interface results from the ammonia plasma pre-clean step, which is described in more detail below. Nitrogen concentration at the interface may be measured by Auger electron spectroscopy (AES) depth profile, with the signal being calibrated by Rutherford backscattering spectroscopy (RBS).

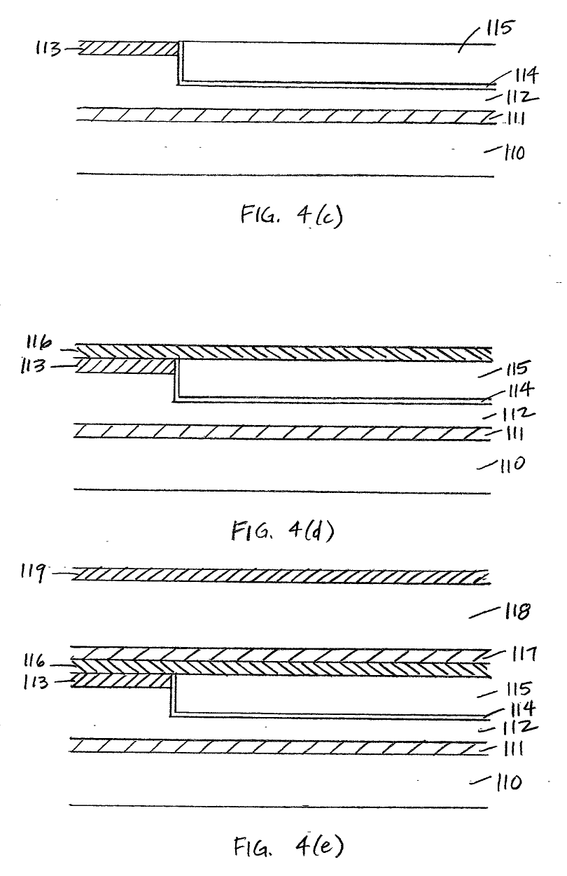

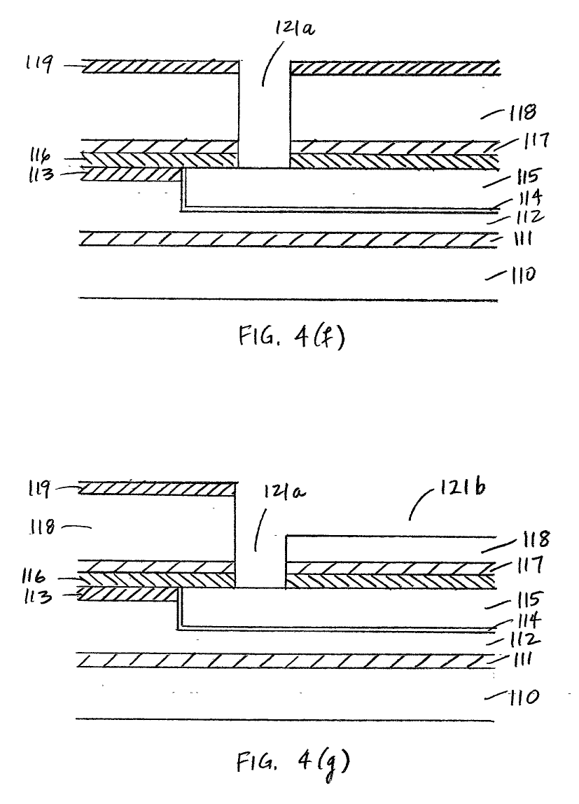

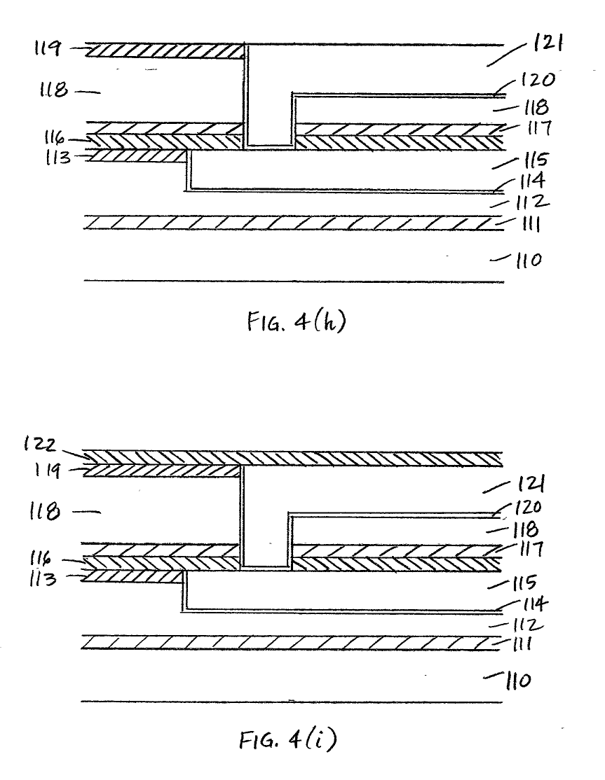

The interconnect structure of FIG. 2 may be formed by a damascene or dual damascene process, such as the process shown in FIGS. 4(a)-4(i). The process preferably begins with deposition of adhesion promoter layer 111 on substrate 110, and is followed by deposition of ILD layer 112 on adhesion promoter layer 111, as shown in FIG. 4(a). Adhesion promoter layer 111 and ILD layer 112 may be deposited by any suitable method. For example, if the adhesion promoter layers are prepared from a solution of vinyltriacetoxysilane in a suitable solvent, the solution is spin coated onto the substrate, and the substrate is heated to about 185° C. for about 90 seconds to remove the solvent. If SiLK™ is used for ILD layer 112, the resin may be applied by a spin-coating process, followed by a baking step to remove solvent and then a thermal curing step.

Hardmask layer 113 is then deposited on ILD layer 112, as shown in FIG. 4(a). Hardmask layer 113 may be deposited by any suitable method, but is preferably deposited by plasma enhanced chemical vapor deposition (PE CVD) directly onto ILD layer 112. The deposition preferably is performed in a PE CVD reactor at a pressure in the range of about 0.1 to 10 torr, most preferably in the range of about 1 to 10 torr, using a combination of gases that may include, but are not limited to, silane (SiH₄), ammonia (NH₃), nitrogen (N₂), helium (He), trimethyl silane (3MS), tetramethyl silane (4MS), or other methyl silanes and hydrocarbon gases. A typical deposition process uses a flow of 3MS in the range of about 50 to 500 sccm and a flow of He in the range of about 50 to 2000 sccm. The deposition temperature is typically within the range of about 150 to 500° C., most preferably in the range of about 300 to 400° C. The radio-frequency (RF) power is typically in the range of about 100 to 700 watts, and most preferably in the range of about 200 to 500 watts. The final deposition thickness is preferably in the range of about 5 to 100 nm, and most preferably in the range of about 25 to 70 nm. Hardmask layer 113 may function as a patterning layer to assist in later etching of ILD layer 112 to form a trench for conductor 115. Hardmask layer 113 may also serve as a polish stop layer during a subsequent CMP step to remove excess metal.

In FIG. 4(b), at least one trench 115a is formed using a conventional photolithography patterning and etching process. In a typical photolithography process, a photoresist material (not shown) is deposited on hardmask layer 113. The photolithography material is exposed to ultraviolet (UV) radiation through a mask, and then the photoresist material is developed. Depending on the type of photoresist material used, exposed portions of the photoresist may be rendered either soluble or insoluble during development. These soluble portions of the photoresist are then removed, leaving behind a photoresist pattern matching the desired pattern of trenches. Trench 115a is then formed by removing hardmask layer 113 and a portion of I)LD layer 112 by, for example, reactive ion etching (RIE), in areas not protected by the photoresist. Hardmask layer 113 may assist in this etching step as follows. Hardmask layer 113 may be etched first in areas not covered by the photoresist, then the photoresist may be removed, leaving behind a patterned hardmask layer 113 matching the photoresist pattern. Then, ILD layer 112 may be etched in areas not covered by hardmask layer 113.

Following formation of trench 115a, the trench is preferably lined with diffusion barrier liner 114, and then a conductive material is deposited in trench 115a to form conductor 115. Diffusion barrier liner 114 may be deposited by any suitable method, such as by physical vapor deposition (PVD) or “sputtering,” or by chemical vapor deposition (CVD). A preferred method for depositing diffusion barrier liner 114 is ionized PVD. The diffusion barrier liner may be a multilayer of metals and metal nitrides deposited by PVD and/or CVD. Conductive material 115 may deposited in trench 115a by any suitable method, such as by electroplating, PVD or CVD. Electroplating is the most preferred method for depositing copper conductive material 115.

Excess liner 114 and conductive material 115 may be removed in a CMP process, in which the top surface of conductor 115 is made coplanar with the hardmask layer 113. Hardmask layer 113 may serve as a polish-stop layer during this CMP step, thereby protecting ILD layer 112 from damage during polishing.

Cap layer 116 is then deposited on conductor 115 and hardmask layer 113, as shown in FIG. 4(d). Cap layer 116 is preferably deposited using a PE CVD process, in a reactor at a pressure in the range of about 0.1 to 20 torr, most preferably in a range of about 1 to about 10 torr, using a combination of gases that may include, but are not limited to, SiH₄, NH₃, N₂, He, 3MS, 4MS, and other methyl silanes.

Prior to deposition of cap layer 116, a plasma cleaning step is preferably performed in the PE CVD reactor. A typical plasma cleaning step uses a source of hydrogen such as NH₃ or H₂ at a flow rate in the range of about 50 to 500 sccm, and is performed at a substrate temperature in the range of about 150 to 500° C., most preferably at a substrate temperature in the range of about 300 to 400° C., for a time of about 5 to 500 seconds and most preferably about 10 to 100 seconds. The RF power is in the range of about 100 to 700 watts, and most preferably in the range of about 200 to 500 watts during this cleaning step. Optionally, other gases such as He, argon (Ar) or N₂ may be added at a flow rate in the range of about 50 to 500 sccm.

Cap layer 116 is then preferably deposited using 3MS or 4MS at a flow rate in the range of about 50 to 500 sccm, He at a flow rate in the range of about 50 to 2000 sccm, and N₂ at a flow rate in the range of about 50 to 500 sccm. The deposition temperature is preferably in the range of about 150 to 500° C., and most preferably in the range of about 300 to 400° C. The RF power is preferably in the range of about 100 to 700 watts, and most preferably in the range of about 200 to 500 watts. The final deposition thickness is preferably in the range of about 10 to 100 nm, and most preferable in the range of about 25 to 70 nm.

FIGS. 4(a)-4(d) illustrate the formation of the first interconnect level, which consists of adhesion promoter layer 111, ILD layer 112, hardmask layer 113, diffusion barrier liner 114, conductor 115 and cap layer 116. In FIG. 4(e), the formation of the second interconnect level begins with deposition of adhesion promoter layer 117, ILD layer 118 and hardmask layer 119. Adhesion promoter layer 117 maybe deposited using the same method as that for adhesion promoter layer 111. Likewise, ILD layer 118 may be deposited using the same method as that for ILD layer 112, and hardmask layer 119 may be deposited using the same method as that for hardmask layer 113.

FIGS. 4(f) and 4(g) illustrate the formation of via 121a and trench 121b. First, at least one via 121 a may be formed in hardmask layer 119, ILD layer 118, adhesion promoter layer 117 and cap layer 116, using a conventional photolithography patterning and etching process, as shown in FIG. 4(f). Then, at least one trench 121b may be formed in hardmask layer 119 and a portion of ILD layer 118, using a conventional photolithography process, as shown in FIG. 4(g). Via 121a and trench 121b may be formed using the same photolithography process as that used to form trench 115a.

Alternatively, via 121a and trench 121b maybe formed by first patterning and etching a trench in hardmask layer 119 and ILD layer 118, where the trench has a depth equal to the depth of trench 121b, but has a length equal to the length of trench 121b and the width of via 121a combined. Then via 121a maybe formed by etching through the remainder of ILD layer 118, adhesion promoter layer 117 and cap layer 116.

Following formation of via 121a and trench 121b, the via and trench are preferably lined with diffusion barrier liner 120, and then a conductive material is deposited in the via and trench to form conductor 121, as shown in FIG. 4(h). Diffusion barrier liner 120 may be deposited by the same method used for diffusion barrier liner 114, and conductive material 121 may deposited by the same method used for conductor 115. Excess liner 120 and conductive material 121 maybe removed in a CMP process, in which the top surface of conductor 121 is made coplanar with the hardmask layer 119. Hardmask layer 119 may serve as a polish-stop layer during this CMP step, thereby protecting ILD layer 118 from damage during polishing.

Cap layer 122 is then deposited on conductor 121 and hardmask layer 119, as shown in FIG. 4(i). Cap layer 122 may be deposited using the same PE CVD process as that for cap layer 116.

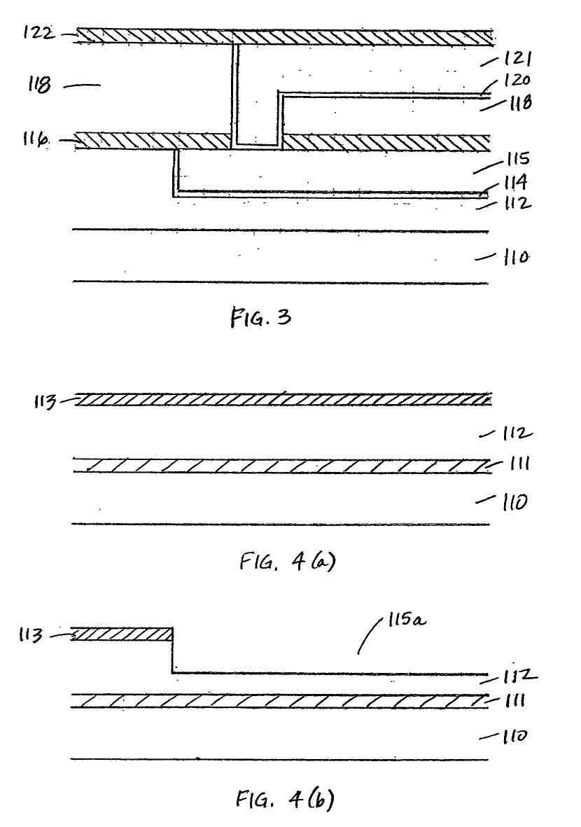

In an alternative embodiment shown in FIG. 3, the interconnect structure of this invention is shown without hardmask layers 113 and 119, and without adhesion promoter layers 111 and 117. In this embodiment, ILD layers 112 and 118 are preferably formed of a silicon-containing dielectric material, such as carbon-doped silicon dioxide (also known as silicon oxycarbide or SiCOH); fluorine-doped silicon oxide (also known as fluorosilicate glass or FSG); spin-on glasses; and silsesquioxanes. The dielectric material is preferably deposited by a chemical vapor deposition (CVD) process, and has a dielectric constant in the range of about 2.0 to 3.5, and most preferably about 2.5 to 3.2. All other materials in the interconnect structure of this embodiment may be the same as the corresponding materials in the interconnect structure shown in FIG. 2. In other words, ILD layers 112 and 118, diffusion barrier liners 114 and 120, conductors 115 and 121 and cap layers 116 and 122 may be formed of the same materials as discussed previously for these layers in the embodiment shown in FIG. 2. Moreover, these layers may be formed using the same processes as discussed previously in relation to FIGS. 4(a)-4(i). Cap layers 116 and 122 should be in strong adhesive contact with conductors 115 and 121 and ILD layers 112 and 118, respectively.

While the present invention has been particularly described in conjunction with a specific preferred embodiment and other alternative embodiments, it is evident that numerous alternatives, modifications and variations will be apparent to those skilled in the art in light of the foregoing description. It is therefore intended that the appended claims embrace all such alternatives, modifications and variations as falling within the true scope and spirit of the present invention.

We claim:

1. An interconnect structure formed on a substrate, the structure comprising:
a dielectric layer overlying the substrate;
a hardmask layer on the dielectric layer, said hardmask layer having a top surface;
at least one conductor embedded in said dielectric layer and having a surface coplanar with the top surface of said hardmask layer; and
a cap layer on said at least one conductor and on said hardmask layer, said cap layer having a bottom surface in strong adhesive contact with said conductor, wherein said cap layer is formed of a material including silicon, carbon, nitrogen and hydrogen.

2. The interconnect structure according to claim 1, further comprising a conductive liner disposed between said conductor and said dielectric layer.

3. The interconnect structure according to claim 1, further comprising an adhesion promoter layer disposed between said dielectric layer and the substrate.

4. The interconnect structure according to claim 1, where in said dielectric layer is formed of an organic thermoset polymer having a dielectric constant of about 1.8 to about 3.5.

5. The interconnect structure according to claim 4, wherein said dielectric layer is formed of a polyarylene ether polymer.

6. The interconnect structure according to claim 1, wherein the material of said cap layer is amorphous nitrogenated hydrogenated silicon carbide and has a dielectric constant of less than about 5.

7. The interconnect structure according to claim 1, wherein the material of said cap layer comprises about 20 to about 34 atomic % Si, about 12 to about 34 atomic % carbon, about 5 to about 30 atomic % nitrogen, and about 20 to about 50 atomic % hydrogen.

8. The interconnect structure according to claim 1, wherein the material of said cap layer comprises about 22 to about 30 atomic % Si, about 15 to about 30 atomic % carbon, about 10 to about 22 atomic % nitrogen, and about 30 to about 45 atomic % hydrogen.

9. The interconnect structure according to claim 1, wherein said hardmask layer is formed of a material including silicon, carbon and hydrogen.

10. The interconnect structure according to claim 9, wherein said hardmask layer is amorphous hydrogenated silicon carbide and has a dielectric constant of less than about 5.

11. The interconnect structure according to claim 9, wherein the material of said hardmask layer comprises about 20 to about 32 atomic % Si, about 20 to about 40 atomic % carbon, and about 30 to about 50 atomic % hydrogen.

12. The interconnect structure according to claim 9, wherein the material of said hardmask layer further comprises about 1 to about 10 atomic % oxygen.

13. The interconnect structure according to claim 1, wherein said conductor is formed of copper.

14. An interconnect structure on a substrate, the structure comprising:
a dielectric layer overlying the substrate, said dielectric layer having a top surface;
at least one conductor embedded in said dielectric layer and having a surface coplanar with the top surface of said dielectric layer; and
a cap layer on said conductor, wherein said cap layer is formed of a material including silicon, carbon, nitrogen and hydrogen.

15. The interconnect structure according to claim 14, wherein said dielectric layer is formed of silicon oxycarbide (SiCOH) or fluorine-doped silicon oxide having a dielectric constant of about 2.0 to about 3.5.

16. The interconnect structure according to claim 14, further comprising a conductive liner disposed between said conductor and said dielectric layer.

17. The interconnect structure according to claim 14, wherein the material of said cap layer is amorphous nitrogenated hydrogenated silicon carbide and has a dielectric constant of less than about 5.

18. The interconnect structure according to claim 14, wherein the material of said cap layer comprises about 20 to about 34 atomic % Si, about 12 to about 34 atomic % carbon, about 5 to about 30 atomic % nitrogen, and about 20 to about 50 atomic % hydrogen.

19. The interconnect structure according to claim 14, wherein the material of said cap layer comprises about 22 to about 30 atomic % Si, about 15 to about 30 atomic % carbon, about 10 to about 22 atomic % nitrogen, and about 30 to about 45 atomic % hydrogen.

20. The interconnect structure according to claim 1, wherein said cap layer comprises less than 1 atomic % oxygen at the bottom surface.

21. The interconnect structure according to claim 1, wherein said cap layer has a first nitrogen concentration at the bottom surface and a second nitrogen concentration at the center of said cap layer, and the first nitrogen concentration is greater than the second nitrogen concentration.

22. A method for forming an interconnect structure on a substrate, the method comprising the steps of:
depositing a dielectric material on the substrate, thereby forming a dielectric layer, said dielectric layer having a top surface;
forming at least one opening in said dielectric layer;
filling said opening with a conductive material, thereby forming at least one conductor, said conductor having a surface coplanar with the top surface of said dielectric layer; and
depositing a cap material on said conductor, said cap material including silicon, carbon, nitrogen and hydrogen, thereby forming a cap layer.

23. The method of claim 18, wherein said cap layer is formed by a method comprising the steps of:
cleaning the substrate using a plasma cleaning process which includes heating the substrate to a temperature of about 150° C. to about 500° C. and exposing the substrate to a source of hydrogen for a time of about 5 to about 500 seconds; and
depositing the cap material using a plasma-enhanced chemical vapor deposition (PE CVD) process which includes placing the substrate into a reactor chamber at a temperature of about 150° C. to about 500° C. and at a pressure of about 0.1 torr to about 20 torr, exposing the substrate to at least one methyl silane compound, and applying RF power of about 100 watts to about 700 watts.

24. A method for forming an interconnect structure on a substrate, the method comprising the steps of:
depositing a dielectric material on the substrate, thereby forming a dielectric layer;
depositing a hardmask material on said dielectric layer, thereby forming a hardmask layer, said hardmask layer having a top surface;
forming at least one opening in said hardmask layer and dielectric layer;
filling said opening with a conductive material, thereby forming at least one conductor, said conductor having a surface coplanar with the top surface of said hardmask layer; and
depositing a cap material on said conductor, said cap material including silicon, carbon, nitrogen and hydrogen, thereby forming a cap layer.
